(19) United States
(12) Patent Application Publication
(10) Pub. No.: US 2013/0113034 A1
(43) Pub. Date: May 9, 2013

(54) NON-VOLATILE SEMICONDUCTOR MEMORY DEVICE, PRODUCTION METHOD FOR SAME, AND CHARGE STORAGE FILM

(71) Applicants: Hideaki Zama, Kanagawa (JP); Makiko Takagi, Kanagawa (JP); Kiyoteru Kobayashi, Kanagawa (JP); Hiroaki Watanabe, Kanagawa (JP); Yu Takahara, Kanagawa (JP)

(72) Inventors: Hideaki Zama, Kanagawa (JP); Makiko Takagi, Kanagawa (JP); Kiyoteru Kobayashi, Kanagawa (JP); Hiroaki Watanabe, Kanagawa (JP); Yu Takahara, Kanagawa (JP)

(73) Assignees: ULVAC, INC., Chigasaki-shi, Kanagawa (JP); TOKAI UNIVERSITY EDUCATIONAL SYSTEM, Tokyo (JP)

(21) Appl. No.: 13/698,903

(22) PCT Filed: Jul. 28, 2011
(86) PCT No.: PCT/JP2011/067309

§ 371 Date: Nov. 19, 2012

(30) Foreign Application Priority Data
Jul. 30, 2010 (JP) 2010-172963

(51) Int. Cl. H01L 29/792

(52) U.S. Cl. 257/324; 438/287

(57) ABSTRACT

A non-volatile semiconductor memory device comprises a tunnel insulating film on a semiconductor substrate, a charge storage film on the tunnel insulating film, a blocking insulating film on the charge storage film, a control gate electrode arranged on the blocking insulating film, and source/drain regions formed on the semiconductor substrate on the both sides of the control gate electrode, that the charge storage film is a silicon nitride film produced according to the catalytic chemical vapor deposition technique and that the ratio between the constituent elements: N/Si falls within the range of from 1.2 to 1.4.

### TECHNICAL FIELD

The present invention relates to a non-volatile semiconductor memory device and a method for the production of the same as well as a charge storage film and more particularly to a non-volatile semiconductor memory device having an MONOS structure or an SONOS structure and a method for the production of the same as well as a charge storage film used for the production of the memory device.

### BACKGROUND ART

There have recently been developed non-volatile semiconductor memory devices such as flash memories as storage media and they have been used for various purposes. With respect to the non-volatile memory device to be loaded into CPU for the production of a mixed discrete chip components-loaded device, there has conventionally been known a memory device such as one having an MONOS (Metal-Oxide-Nitride-Oxide-Silicon) structure (MONOS type memory cell structure) or an SONOS (Silicon-Oxide-Nitride-Oxide-Silicon) structure (SONOS type memory cell structure), which makes use of a silicon nitride film prepared according to the LPCVD technique (see, for instance, Patent Document 1 specified below). The memory having such a structure never loses its storage or memory even after cutting the power supply, and it would permit the quick writing and reading out.

In the case of the aforementioned non-volatile semiconductor memory device, the floating gate type memory device is one of the leading mainstreams thereof and this floating gate serves as a region for storing and retaining charges. In the conventional non-volatile semiconductor memory device, a floating gate (for instance, a polycrystalline silicon film) is formed on a tunnel insulating film (this is also referred to as “gate insulating film” and consists of a silicon oxide film or the like) which is deposited on a semiconductor substrate and through which charges can selectively pass and a control gate electrode is further formed on the floating gate through a blocking insulating film (for instance, a silicon oxide film or an aluminum oxide film) and source/drain regions are formed on the semiconductor substrate on the both sides of the control gate electrode. The blocking insulating film can function to obstruct the passage of any electric current between the floating gate as a charge storage film and the control electrode.

In an example of such a memory device in which an Si₃N₄ film is used as such a floating gate, there has been known, for instance, a non-volatile semiconductor memory device in which a silicon nitride film is formed on a tunnel insulating film (such as a silicon oxide film) provided on a semiconductor substrate, according to the LPCVD technique, a control gate electrode is formed on the silicon nitride film through a blocking insulating film (such as a silicon oxide film) and source/drain regions are formed on the semiconductor substrate on the both sides of the control gate electrode.

According to the aforementioned memory device, upon the writing of data to the memory, it is common that the source electrode is grounded; a sufficiently high electric voltage is applied to the gate electrode and the drain electrode to thus transfer electrons from the source electrode to the drain electrode. As a result, the electrons travelling through the channel region are converted into thermoelectrons each having a high momentum and a part of the thermoelectrons can pass through the tunnel insulating film and they are stored or accommodated in the floating gate. Even though the gate is closed after a sufficient quantity of electrons are stored in the floating gate, the electrons stored in the floating gate can be retained therein because of the interruption or inhibitory effect of the tunnel insulating film. In other words, information is surely stored in the memory device. Contrary to this, when erasing the information stored therein, the gate electrode is grounded and the source electrode is maintained at a high voltage. Thus, electrons gradually escape from the floating gate and the information stored therein is erased.

In this way, the floating gate type non-volatile semiconductor memory device should satisfy such requirements that the floating gate is correctly charged with electrical charges and that the floating gate retains the charged electric charges over a long period of time (for instance, it is said that the term is not less than 10 years).

There has recently been a tendency to miniaturize the integrated circuit and even in the field of the non-volatile semiconductor memory device, there has been actualized such tendency to miniaturize the memory device and to substantially increase the memory capacity thereof and accordingly, it has strongly been desired for the development of techniques which can satisfy these requirements. For this reason, it has been desired for the memory device to miniaturize and to substantially increase the memory capacity through the improvement of the charge-retaining characteristics, even in the case of the floating gate type non-volatile semiconductor memory device, which makes use of a silicon nitride film as the charge storage film.

Proposed as a charge storage film to be used in the non-volatile semiconductor memory device having the aforementioned structure is one at least comprising an Si₃N₄ film and an insulating film which is formed on the silicon nitride film and which contains La and Si (see, for instance, Patent Document 2 specified below). This silicon nitride film is formed according to the usual CVD technique and it has been said that the quantity of trapped electric charges is increased if the charge storage film is designed so as to have such a laminated structure.

Furthermore, it has been known that a silicon nitride film can be prepared using SiH₄ gas and NH₃ gas according to the catalytic chemical vapor deposition technique (Cat-CVD technique) (see, for instance, Patent Document 3 specified below).

### PRIOR ART LITERATURE

### Patent Document

[Patent Document 1] JP 2002-190535A;
[Patent Document 2] JP 2009-194311A;
[Patent Document 3] JP 563-40314A.

### DISCLOSURE OF THE INVENTION

### Problems that the Invention is to Solve

Regarding the non-volatile semiconductor memory device which has an MONOS structure or an SONOS structure and which makes use of a silicon nitride film prepared according to the aforementioned LPCVD technique, it has been pointed out that there is a limit in the degree of miniaturization of such a memory device because of the limit in the charge storage capacity of this Si₃N₄ film. For this reason, it has been desired to improve the ability of the Si₃N₄ film to store and retain charges (the charge-retaining characteristics). In other words, regarding the floating gate type non-volatile semiconductor memory device, it has been pointed out that there is a fundamental limit in the miniaturization of the individual constituent film and accordingly, there has been desired for the improvement of the charge storage capacity of the charge storage film.

Accordingly, it is an object of the present invention to solve the problems associated with the foregoing conventional techniques and more specifically to provide a non-volatile semiconductor memory device, which has a structure such as an MONOS structure or an SONOS structure, which is provided with a charge storage film consisting of a silicon nitride film having high charge-storing and retaining characteristics and which can be miniaturized. It is another object of the present invention to provide a method for the production of such a memory device as well as such a charge storage film.

### Means for the Solution of the Problems

The non-volatile semiconductor memory device according to the present invention is characterized in that it comprises a tunnel insulating film on the top of a semiconductor substrate, a charge storage film on the top of the tunnel insulating film, a blocking insulating film on the top of the charge storage film, a control gate electrode arranged on the top of the blocking insulating film, and source/drain regions formed on the semiconductor substrate on the both sides of the control gate electrode, that the charge storage film is a silicon nitride film produced according to the catalytic chemical vapor deposition technique and that the ratio between the constituent elements: N/Si falls within the range of from 1.2 to 1.4.

If the silicon nitride film prepared according to the aforementioned catalytic chemical vapor deposition technique is used as a charge storage film, the quantity of charges stored in the non-volatile semiconductor memory device is correspondingly increased and the charge-retaining characteristics of the memory device is improved. Accordingly, the scale of the non-volatile semiconductor memory device can be micronized.

In this respect, if the foregoing N/Si ratio is less than 1.2, there would be observed such a tendency that the ability of the resulting memory device to store and/or retain charges is deteriorated, while if the ratio is higher than 1.4, the insulating properties of the memory device is apt to be impaired.

The non-volatile semiconductor memory device according to the present invention is characterized in that the content of the hydrogen atoms introduced into the foregoing silicon nitride film according to the catalytic chemical vapor deposition technique falls within the range of from 5 to 20 at %.

This is because, if the content of the introduced hydrogen atoms is less than 5 at %, there would be observed such a tendency that the ability of the resulting memory device to store and/or retain charges is deteriorated, while if the content thereof exceeds 20 at %, the insulating properties of the memory device is apt to be impaired.

The non-volatile semiconductor memory device according to the present invention is further characterized in that the number, per unit volume, of the N—H bonds introduced into the foregoing silicon nitride film according to the catalytic chemical vapor deposition technique falls within the range of from 5×10²¹ to 5×10²² bonds/cm³.

This is because, if the number, per unit volume, of the N—H bonds introduced is less than 5×10²¹ bonds/cm³, there would be observed such a tendency that the ability of the resulting memory device to store and/or retain charges is deteriorated, while if the number, per unit volume, of the N—H bonds exceeds 5×10²² bonds/cm³, the insulating properties of the memory device is apt to be impaired.

The non-volatile semiconductor memory device of the present invention is characterized in that it comprises a tunnel insulating film on the top of a semiconductor substrate, a charge storage film on the top of the tunnel insulating film, a blocking insulating film on the top of the charge storage film, a control gate electrode arranged on the top of the blocking insulating film, and source/drain regions formed on the semiconductor substrate on the both sides of the control gate electrode, that the charge storage film is a silicon nitride film produced according to the catalytic chemical vapor deposition technique, that the ratio between the constituent elements: N/Si falls within the range of from 1.2 to 1.4, that the content of the hydrogen atoms introduced into the foregoing silicon nitride film according to the catalytic chemical vapor deposition technique falls within the range of from 5 to 20 at %, and that the number, per unit volume, of the N—H bonds introduced into the silicon nitride film according to the catalytic chemical vapor deposition technique falls within the range of from 5×10²¹ to 5×10²² bonds/cm³.

The non-volatile semiconductor memory device of the present invention is characterized in that the silicon nitride film is one prepared according to the catalytic chemical vapor deposition technique in which SiH₄ gas and NH₃ gas are introduced into a vacuum chamber and decomposed by bringing these gases into close contact with a heated catalyst, and the resulting decomposition products are deposited on a heated surface of a subject arranged within the vacuum chamber to thus form a desired silicon nitride film on the subject surface.

The non-volatile semiconductor memory device of the present invention is characterized in that the silicon nitride film is one prepared according to the catalytic chemical vapor deposition technique, while the ratio of the introduced amount (sccm) of the SiH₄ gas to that of the NH₃ gas: NH₃/SiH₄ is set at a level ranging from 1 to 500.

This is because if the ratio between the gases introduced into the chamber is beyond the range specified above, there would be observed such a tendency that it is quite difficult to obtain any desired silicon nitride film.

The non-volatile semiconductor memory device of the present invention is characterized in that the silicon nitride film is one prepared according to the catalytic chemical vapor deposition technique, in which SiH₄ gas, NH₃ gas and H₂ gas are introduced into a vacuum chamber and decomposed by bringing these gases into close contact with a heated catalyst, and the resulting decomposition products are deposited on a heated surface of a subject arranged within the vacuum chamber to thus form a desired silicon nitride film on the subject surface.

The non-volatile semiconductor memory device of the present invention is characterized in that the silicon nitride film is one prepared according to the catalytic chemical vapor deposition technique, while the ratios between the amounts (sccm) of the introduced gases, i.e., SiH₄ gas, NH₃ gas and H₂ gas, or the ratio: (NH₃+H₂)/SiH₄ and the ratio: NH₃/(NH₃+H₂) are set at levels ranging from 1 to 500 and 0.01 to 1, respectively.

This is because, if each of the ratios between these gases introduced into the chamber is beyond the corresponding range specified above, there would be observed such a tendency that it is quite difficult to obtain any desired silicon nitride film.

The non-volatile semiconductor memory device of the present invention is characterized in that the silicon nitride film is one prepared according to the catalytic chemical vapor deposition technique, in which the pressure in the vacuum chamber is set at a level of less than 100 Pa. In this connection, the lower limit of the pressure is one currently achievable.

This is because, if the pressure exceeds 100 Pa, there would be observed such a tendency that it is quite difficult to obtain any desired silicon nitride film.

The non-volatile semiconductor memory device of the present invention is characterized in that the temperature of the heated surface of the subject ranges from 100 to 500° C.

That is to say, if the temperature of the heated surface of the subject is outside the range specified above, there would be observed such a tendency that it is quite difficult to obtain any desired silicon nitride film.

The non-volatile semiconductor memory device of the present invention is characterized in that the catalyst consists of a material selected from the group consisting of at least one metal selected from W, Mo and Ta, and alloys each consisting of at least two of these metals.

The non-volatile semiconductor memory device of the present invention is characterized in that the temperature of the heated catalyst ranges from 1,500 to 2,000° C.

That is to say, if the temperature of the heated catalyst is out of the range specified above, there would be observed such a tendency that it is quite difficult to obtain any desired silicon nitride film.

The method for the preparation of a non-volatile semiconductor memory device according to the present invention is characterized in that it comprises the steps of forming a tunnel insulating film on a semiconductor substrate; forming, on the tunnel insulating film, a silicon nitride film which can serve as a charge storage film and in which the ratio between the constituent elements: N/Si falls within the range of from 1.2 to 1.4, according to the catalytic chemical vapor deposition technique; forming a blocking insulating film on the charge storage film; forming a control gate electrode on the blocking insulating film; and forming source/drain regions on the semiconductor substrate on the both sides of the control gate electrode.

The foregoing method for the preparation of a non-volatile semiconductor memory device is characterized in that the content of the hydrogen atoms introduced into the foregoing silicon nitride film according to the catalytic chemical vapor deposition technique falls within the range of from 5 to 20 at %.

The foregoing method for the preparation of a non-volatile semiconductor memory device is characterized in that the number, per unit volume, of the N—H bonds introduced into the silicon nitride film according to the catalytic chemical vapor deposition technique falls within the range of from 5×10²¹ to 5×10²² bonds/cm³.

The foregoing method for the preparation of a non-volatile semiconductor memory device is characterized in that the silicon nitride film is prepared according to the catalytic chemical vapor deposition technique in which SiH₄ gas and NH₃ gas are introduced into a vacuum chamber and decomposed by bringing these gases into close contact with a heated catalyst, and the resulting decomposition products are deposited, on a heated surface of a subject arranged within the vacuum chamber to thus form a desired silicon nitride film on the substrate surface.

The foregoing method for the preparation of a non-volatile semiconductor memory device is characterized in that the silicon nitride film is prepared according to the catalytic chemical vapor deposition technique, while the ratio of the introduced amount (sccm) of the SiH₄ gas to that of the NH₃ gas: NH₃/SiH₄ is set at a level ranging from 1 to 500.

The foregoing method for the preparation of a non-volatile semiconductor memory device is characterized in that the silicon nitride film is prepared according to the catalytic chemical vapor deposition technique in which SiH₄ gas, NH₃ gas and H₂ gas are introduced into a vacuum chamber and decomposed by bringing these gases into close contact with a heated catalyst and the resulting decomposition products are deposited on a heated surface of a subject arranged within the vacuum chamber to thus form a desired silicon nitride film on the subject surface.

The foregoing method for the preparation of a non-volatile semiconductor memory device is characterized in that the silicon nitride film is prepared according to the catalytic chemical vapor deposition technique, while the ratios between the amounts of the introduced gases, i.e., SiH₄ gas, NH₃ gas and H₂ gas, or the ratio: (NH₃+H₂)/SiH₄ and the ratio: NH₃/(NH₃+H₂) are set at levels ranging from 1 to 500 and 0.01 to 1, respectively.

The foregoing method for the preparation of a non-volatile semiconductor memory device is characterized in that the silicon nitride film is prepared according to the catalytic chemical vapor deposition technique, in which the pressure in the vacuum chamber is set at a level of less than 100 Pa.

The foregoing method for the preparation of a non-volatile semiconductor memory device is characterized in that the temperature of the heated surface of the subject ranges from 100 to 500° C.

The foregoing method for the preparation of a non-volatile semiconductor memory device is characterized in that the catalyst consists of a material selected from the group consisting of at least one metal selected from W, Mo and Ta, and alloys each consisting of at least two of these metals.

The foregoing method for the preparation of a non-volatile semiconductor memory device is characterized in that the temperature of the heated catalyst ranges from 1,500 to 2,000° C.

The charge storage film according to the present invention is characterized in that the charge storage film is a silicon nitride film, prepared according to the catalytic chemical vapor deposition technique, in which the ratio between the constituent elements: N/Si falls within the range of from 1.2 to 1.4.

The charge storage film according to the present invention is characterized in that the silicon nitride film contains the hydrogen atoms introduced into the same according to the catalytic chemical vapor deposition technique, which falls within the range of from 5 to 20 at %.

The charge storage film according to the present invention is characterized in that the silicon nitride film has the number, per unit volume, of the N—H bonds introduced into the same according to the catalytic chemical vapor deposition technique, which falls within the range of from 5×10²¹ to 5×10²² bonds/cm³.

### Effects of the Invention

The present invention permits the achievement of such an effect that a non-volatile semiconductor memory device (for instance, a memory device having an MONOS structure or an SONOS structure) can be provided, which can eliminate any limit in the scale down or the micronization and which has a high degree of integration, through the use of a charge storage film having a high charge-retaining characteristics. This is because the memory device comprises a charge storage film consisting of a silicon nitride film prepared according to the catalytic chemical vapor deposition technique.

### BRIEF DESCRIPTION OF THE DRAWINGS

FIG. 1 is a side view schematically showing an example of the construction of a non-volatile semiconductor memory device having an MONOS structure, as an embodiment of the present invention.

FIG. 2 is a side view schematically showing an example of the construction of a film-forming apparatus used for the production of a silicon nitride film according to the present invention.

FIG. 3 is a graph showing the relation between the N/Si ratio and the mid-gap voltage (V) observed for the silicon nitride film prepared in Example 1, wherein the graph is prepared for the investigation of any effect of the N/Si ratio in the silicon nitride film on the memory window (V) of the resulting memory device.

FIG. 4 is a graph showing the relation between the retention time (sec) and the mid-gap voltage (V) observed for the silicon nitride film prepared in Example 2 according to the catalytic chemical vapor deposition technique, wherein the graph is prepared for the investigation of the charge-retaining characteristics of the silicon nitride film.

FIG. 5 is a graph showing the relation between the retention time (sec) and the mid-gap voltage (V) observed for the silicon nitride film prepared according to the conventional LPCVD technique, wherein the graph is prepared for the investigation of the charge retaining characteristics of the silicon nitride film.

FIG. 6 is a graph showing the Arrhenius plot prepared by summarizing the results obtained in Example 2.

FIG. 7 is a table in which there are summarized the results of the charge-retaining characteristics observed for the silicon nitride film prepared in Example 2 according to the catalytic chemical vapor deposition technique; an Si₃N₄ film prepared according to the LPCVD technique; and an Si₃N₄ film prepared according to the PECVD technique, while these results are compared with one another.

### MODE FOR CARRYING OUT THE INVENTION

According to an embodiment of the non-volatile semiconductor memory device of the present invention, the non-volatile semiconductor memory device comprises a tunnel insulating film on the top of a semiconductor substrate, a charge storage film on the top of the tunnel insulating film, a blocking insulating film on the top of the charge storage film, a control gate electrode arranged on the top of the blocking insulating film, and source/drain regions formed on the semiconductor substrate on the both sides of the control gate electrode, wherein the charge storage film is a silicon nitride film produced according to the catalytic chemical vapor deposition technique, in which the ratio between the constituent elements: N/Si, as determined according to the method as will be described below, falls within the range of from 1.2 to 1.4, the content of the hydrogen atoms introduced into the foregoing silicon nitride film according to the catalytic chemical vapor deposition technique falls within the range of from 5 to 20 at %, as determined according to the method specified below, and the number, per unit volume, of the N—H bonds introduced into the silicon nitride film according to the catalytic chemical vapor deposition technique falls within the range of from 5×10²¹ to 5×10²² bonds/cm³, as determined according to the method specified below.

The ratio between the constituent elements: N/Si can be determined by the Rutherford Backscattering Spectroscopy technique. More specifically, the ratio is herein determined according to the method in which a sample is irradiated with He ions each having an energy of 480 keV at an angle of 45 degrees with respect to the line normal to the sample surface and the scattered He ions are detected at a scattering angle of 90 degrees using a magnetic field-deflected energy analyzer.

The content of the hydrogen atoms introduced into the silicon nitride film can be determined by the Elastic Recoil Detection Analysis. More specifically, the content of the hydrogen atoms is herein determined according to the method in which a sample is irradiated with N⁺ ions each having an energy of 480 keV at an angle of 70 degrees with respect to the line normal to the sample surface and the recoiled H⁺ ions are detected at a scattering angle of 30 degrees using a magnetic field-deflected energy analyzer.

The number of the N—H bonds, per unit volume, can be determined according to the Fourier Transform Infrared Spectroscopy technique. Each specific number of the bonds was calculated using the conversion factor disclosed in the article of W. A. Lanford, M. J. Rand (J. Appl. Phys., 1978, 49: 2473).

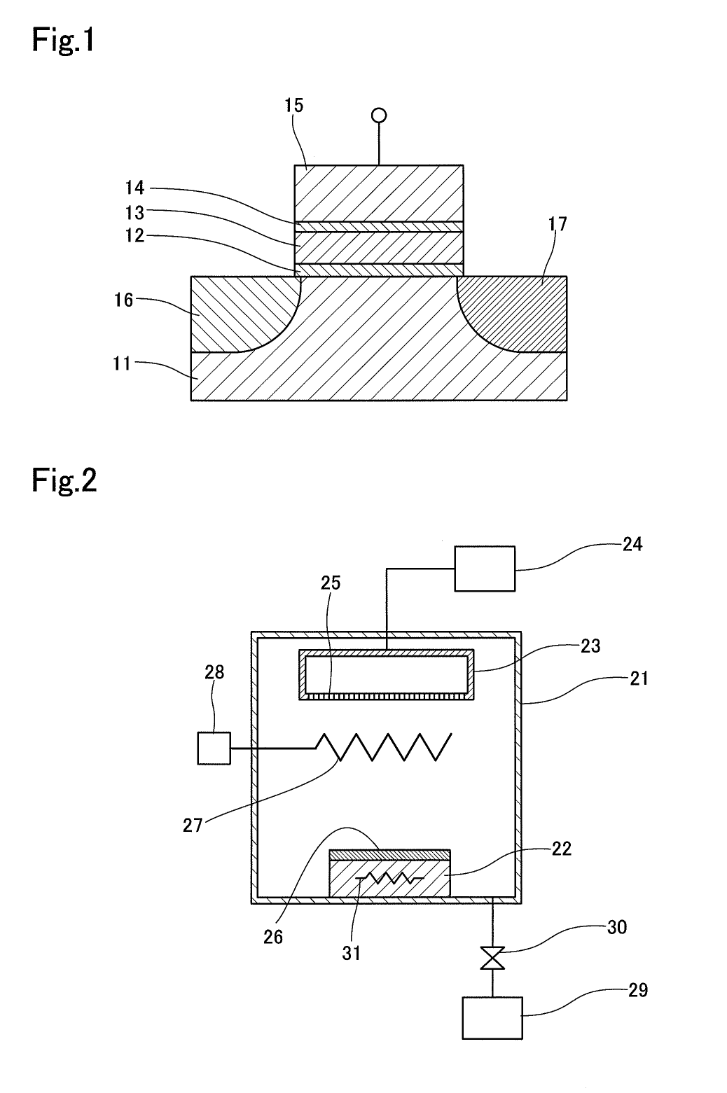

If the non-volatile semiconductor memory device according to the present invention has such an MONOS structure as shown in FIG. 1, the memory device comprises a tunnel insulating film 12 consisting of a silicon oxide (SiO₂) film formed on an Si substrate 11, a charge storage film 13 consisting of a silicon nitride film formed on the tunnel insulating film 12, a blocking insulating film 14 consisting of a silicon oxide (SiO₂) film formed on the charge storage film 13, a control gate electrode 15 consisting of a polysilicon film or a metal film applied onto the blocking insulating film 14, and a source region 16 and a drain region 17 which are formed on the Si substrate 11 on the both sides of the control gate electrode 15, and the memory device is so designed that an electric voltage can be applied to the control gate electrode 15. The blocking insulating film 14 has such a function to stop or interrupt the passage of any electric current between the floating gate or the charge storage film 13 and the control gate electrode 15.

Information can be stored in the foregoing silicon nitride film by making the charge-trapping center of the film capture holes or positive holes and/or electrons. The use of the charge storage film consisting of the silicon nitride film according to the present invention would be able to not only cope with the requirements for the high degree of integration and the high speed operation of the non-volatile semiconductor memory device, but also cope with the scale down or micronization of the memory device.

The foregoing silicon nitride film can be produced according to the catalytic chemical vapor deposition technique which comprises, for instance, the steps of introducing SiH₄ gas and NH₃ gas into a vacuum chamber at a ratio between the amounts (sccm) of these gases introduced or the ratio: NH₃/SiH₄ ranging from 1 to 500, or introducing SiH₄ gas, NH₃ gas and H₂ gas into a vacuum chamber at ratios between the amounts (sccm) of these gases introduced or the ratio: (NH₃+H₂)/SiH₄ and the ratio: NH₃/(NH₃+H₂) set at levels ranging from 1 to 500 and 0.01 to 1, respectively; decomposing these gases by bringing them into close contact with a catalyst which is heated to a temperature ranging from 1,500 to 2,000° C. and which consists of a material selected from the group consisting of at least one metal selected from W, Mo and Ta and alloys each comprising at least two of these metals, while the pressure within the vacuum chamber is set at a level ranging from 1 to 100 Pa; and then depositing the resulting decomposition products on the surface of a subject whose surface temperature is raised up to a level ranging from 100 to 500° C. to thus give a desired silicon nitride film.

In an embodiment of the method for the production of a non-volatile semiconductor memory device according to the present invention, the production method comprises the steps of forming a tunnel insulating film on a semiconductor substrate; forming a silicon nitride film or a charge storage film on the tunnel insulating film, according to the catalytic chemical vapor deposition technique in which a gas mixture comprising SiH₄ gas and NH₃ gas at a ratio between the amounts of these gases or the ratio: NH₃/SiH₄ ranging from 1 to 500 is brought into close contact with a catalyst (for instance, at least one metal selected from the group consisting of W, Mo and Ta as well as an alloy comprising at least two of these metals) heated to a temperature ranging from 1,500 to 2,000° C. to thus decompose the gases and to thereby form a desired film of the resulting silicon nitride on the heated surface of the subject, in which the ratio between the constituent elements: N/Si falls within the range of from 1.2 to 1.4, the content of the hydrogen atoms introduced into the same falls within the range of from 5 to 20 at %, and the number, per unit volume, of the N—H bonds introduced into the same falls within the range of from 5×10²¹ to 5×10²² bonds/cm³; forming a blocking insulating film on the charge storage film; forming a control gate electrode on the blocking insulating film; and then forming source/drain regions on the semiconductor substrate on the both sides of the control gate electrode.

According to a further embodiment of the foregoing method for the production of a non-volatile semiconductor memory device, the method is characterized in that the silicon nitride film is prepared according to the catalytic chemical vapor deposition technique and more specifically, the silicon nitride film is prepared by bringing a gas mixture consisting of SiH₄ gas, NH₃ gas and H₂ gas into close contact with a heated catalyst to thus decompose these gases, wherein the ratios between the amounts (sccm) of these gases introduced or the ratio: (NH₃+H₂)/SiH₄ and the ratio: NH₃/(NH₃+H₂) are set at levels ranging from 1 to 500 and 0.01 to 1, respectively; and then depositing the resulting decomposition products on the heated surface of a subject to thus form a desired silicon nitride film or a charge storage film having the aforementioned ratio between the constituent elements (N/Si ratio), content of the hydrogen atoms introduced into the film and number, per unit volume, of the N—H bonds introduced into the same.

According to a still further embodiment of the foregoing method for the production of a non-volatile semiconductor memory device, the silicon nitride film is prepared according to the catalytic chemical vapor deposition technique, while the pressure within the vacuum chamber is set at a level of less than 100 Pa and the temperature of the heated surface of the subject is set at a level ranging from 100 to 500° C.

According to an embodiment of the charge storage film of the present invention, this charge storage film is a silicon nitride film prepared according to the catalytic chemical vapor deposition technique, in which the ratio between the constituent elements: N/Si, as determined according to the method described above, falls within the range of from 1.2 to 1.4, the content of the hydrogen atoms introduced into the silicon nitride film according to the catalytic chemical vapor deposition technique falls within the range of from 5 to 20 at %, as determined according to the method described above, and the number, per unit volume, of the N—H bonds introduced into the silicon nitride film according to the catalytic chemical vapor deposition technique falls within the range of from 5×10²¹ to 5×10²² bonds/cm³, as determined according to the method described above.

The films constituting the foregoing non-volatile semiconductor memory device other than the charge storage film may be those prepared according to any known film-forming method. For instance, the semiconductor substrate usable herein may be a variety of semiconductor substrates such as an Si substrate; usable herein as the tunnel insulating film which is applied onto the semiconductor substrate and selectively allows charges to pass through the same may be, for instance, a silicon oxide film or an aluminum oxide film; usable herein as the blocking insulating film formed thereon may be, for instance, a silicon oxide film or an aluminum oxide film; the control gate electrode to be applied onto the blocking insulating film may be prepared from, for instance, polysilicon or aluminum, and the source/drain regions are formed according to, for instance, the thermal diffusion technique or the ion implantation technique.

The foregoing silicon nitride film can be formed using a film-forming apparatus whose construction is schematically shown in FIG. 2. The film-forming apparatus as shown in FIG. 2 comprises a vacuum chamber 21, a table 22 for mounting a substrate (a subject on which a film is to be formed), is arranged within the vacuum chamber 21 and a nozzle 23 for introducing a raw gas into the chamber and for supplying the same on the substrate is also arranged within the chamber at a position opposite to the substrate-mounting table 22. The nozzle 23 is connected to a raw gas-supply system 24. In FIG. 2, only one raw gas-supply system is depicted, but the film-forming apparatus is in general provided with a plurality of raw gas-supply systems corresponding to the number of raw gases to be introduced into the vacuum chamber. Usable herein as such raw gases may be, for instance, a combination of SiH₄ and NH₃ gases or a combination of SiH₄, NH₃ and H₂ gases.

The nozzle 23 is provided with a plurality of holes 25 in the bottom surface thereof at positions facing the substrate-mounting table 22 and more specifically, the film-forming apparatus is so designed that the raw gas can be injected into the vacuum chamber and sprayed on the surface of a substrate 26 which is to be placed on the substrate-mounting table 22 upon the formation of a film, when the raw gas accommodated in the raw gas-supply system 24 is introduced into the vacuum chamber 21 through the holes 25 of the nozzle 23.

Positioned between the nozzle 23 and the substrate-mounting table 22 is a catalyst 27 in a filament-like shape, which consists of a material selected from the group consisting of at least one metal selected from W, Mo and Ta, and alloys each consisting of at least two of these metals. The catalyst 27 can be heated to a temperature of, for instance, not less than 1,500° C. and not higher than 2,000° C. (for instance, 1,700° C.) by the passage of an electric current through the catalyst using a power supply 28 which is arranged outside the vacuum chamber 21, when it is used in the formation of a silicon nitride film.

In addition, a vacuum pump 29 is connected to the vacuum chamber 21 through a variable valve 30 and the vacuum chamber 21 is so designed that the pressure within the vacuum chamber 21 can be set at a predetermined level by exhausting the same with the vacuum pump 29, that the substrate 26 can be placed on the substrate-mounting table 22, while maintaining such a vacuum condition within the vacuum chamber and that the temperature of the substrate 26 can be raised up to a level of not less than 100° C. and not higher than 500° C. through the use of a heating means 31 such as a heater arranged in the interior of the substrate-mounting table 22 so that a silicon nitride film can thus be formed on the substrate.

The following is the description of the method for the production of a silicon nitride film using the film-forming apparatus as shown in FIG. 2. After raising the temperature of the substrate 22 according to the foregoing manner, the degree of opening of the variable valve 30 is changed to thus reduce the evacuation speed of the vacuum pump 29, the raw gases (a combination of SiH₄ gas and NH₃ gas, or a combination of SiH₄ gas, NH₃ gas and gas H₂ gas) are introduced into the vacuum chamber 21 through the nozzle 23 while controlling the flow rates of the gases in such a manner that the vacuum chamber 21 is filled with the atmosphere of these raw gases to a pressure of less than 100 Pa.

When the raw gases introduced into the vacuum chamber 21 are brought into close contact with a heated catalyst 27, each raw gas is thus decomposed to form radicals corresponding to the individual raw gas. When these radicals reach the surface of the substrate 26, a silicon nitride film is correspondingly formed on the surface of the substrate 26.

In the following Examples, as element experiments for the evaluation of the effectiveness of the charge storage film consisting of a silicon nitride film, the capacitor obtained by depositing silicon oxide on a silicon substrate is inspected for the effectiveness.

### EXAMPLE 1

In this Example, a silicon nitride film was formed on a silicon substrate, according to the catalytic chemical vapor deposition technique under the following film-forming conditions, using a film-forming apparatus as shown in FIG. 2 and using silane (SiH₄) and ammonia (NH₃) as raw gases: the flow rate of each of the raw gases: 4 to 7 sccm; the film-forming temperature: 400° C.; the pressure in the vacuum chamber: 10 Pa; and the temperature of the catalyst: 1,700° C. In this case, the compositional ratio: N/Si was variously changed for the investigation of the relation between the compositional ratio: N/Si and the mid-gap voltage (V).

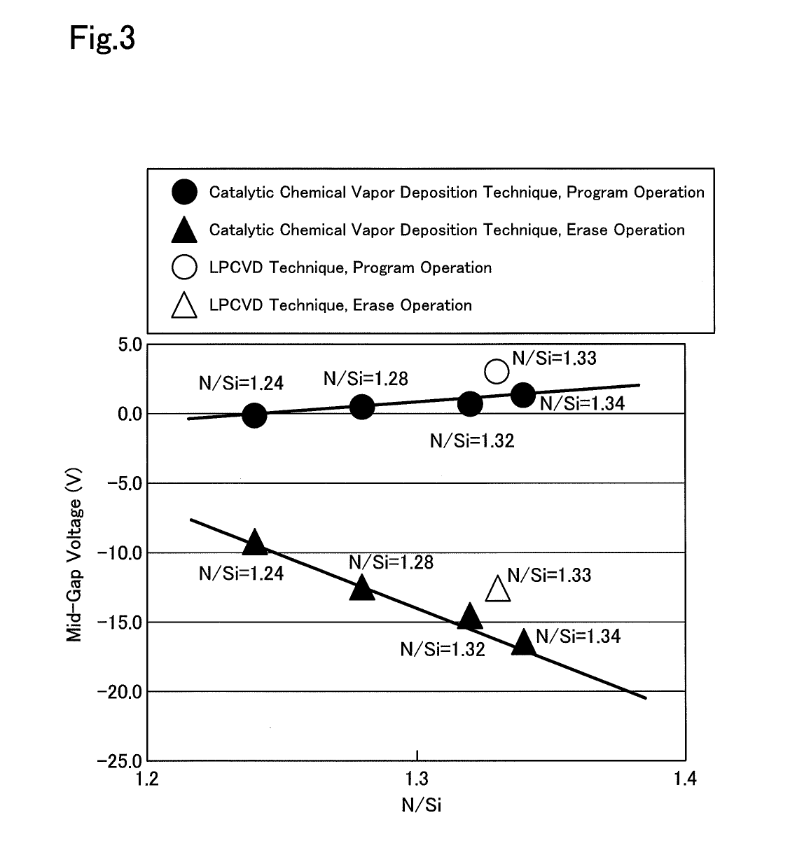

The silicon nitride films thus prepared and having N/Si ratios of 1.24, 1.28, 1.32 and 1.34, respectively were inspected for the mid-gap voltage (V) observed when they were subjected to program operations and erase operations, while the program voltage and the erase voltage were set at +22V and −25V, respectively. The results thus obtained are summarized in the following Table 1 and they are also plotted on FIG. 3. In this connection, the term “mid-gap voltage” herein used means the gate voltage observed when the Fermi level of silicon on the silicon surface is in agreement with the central value of the bandgap or forbidden band. In FIG. 3, the N/Si ratio is plotted as abscissa and the mid-gap voltage (V) is plotted as ordinate. Moreover, the difference between the mid-gap voltages observed during the program operation and the erase operation is herein defined to be memory window (V).

TABLE 1

| | Flow Rate of | N/Si | Mid-Gap Voltage (V) | | Memory |
|---|---|---|---|---|---|
| | SiH₄ (sccm) | Ratio | Program | Erase | Window (V) |
| Cat- | 4 | 1.34 | 1.4 | −16.4 | 17.8 |
| CVD | 5 | 1.32 | 0.8 | −14.5 | 15.3 |
| | 6 | 1.28 | 0.5 | −12.5 | 13.0 |
| | 7 | 1.24 | −0.1 | −9.3 | 9.2 |
| LPCVD | — | 1.33 | 3.1 | −12.6 | 15.7 |

The data shown in Table 1 and plotted on FIG. 3 clearly indicate that when the N/Si ratio is not less than 1.33 in the case of the present invention, the memory window (V) is wider than that observed for the film prepared using silane dichloride (SiH₂Cl₂) and NH₃ as raw gases, according to the LPCVD technique at a film-forming temperature of 750° C., a pressure of 30 Pa, while it is slightly lower than the latter, in the case where the N/Si ratio is less than 1.33. For this reason, it would be concluded that a memory window superior to that observed for the film prepared according to the LPCVD technique can surely be ensured, so long as the N/Si ratio of the film of the present invention is not less than 1.33.

In Example 1 and the following Example 2, the silicon nitride films are formed according to the catalytic chemical vapor deposition technique at a low film-forming temperature on the order of 400° C. in Example 1 and 300° C. in Example 2. In this way, if a silicon nitride film is prepared at a low temperature according to the catalytic chemical vapor deposition technique, a higher or wider memory window of the silicon nitride film can be ensured, which is superior to that achieved by the silicon nitride film prepared at a high temperature of 750° C. according to the LPCVD technique. According to the catalytic chemical vapor deposition technique used in the present invention, the film-forming temperature can considerably be reduced as compared with that used in the LPCVD technique.

### EXAMPLE 2

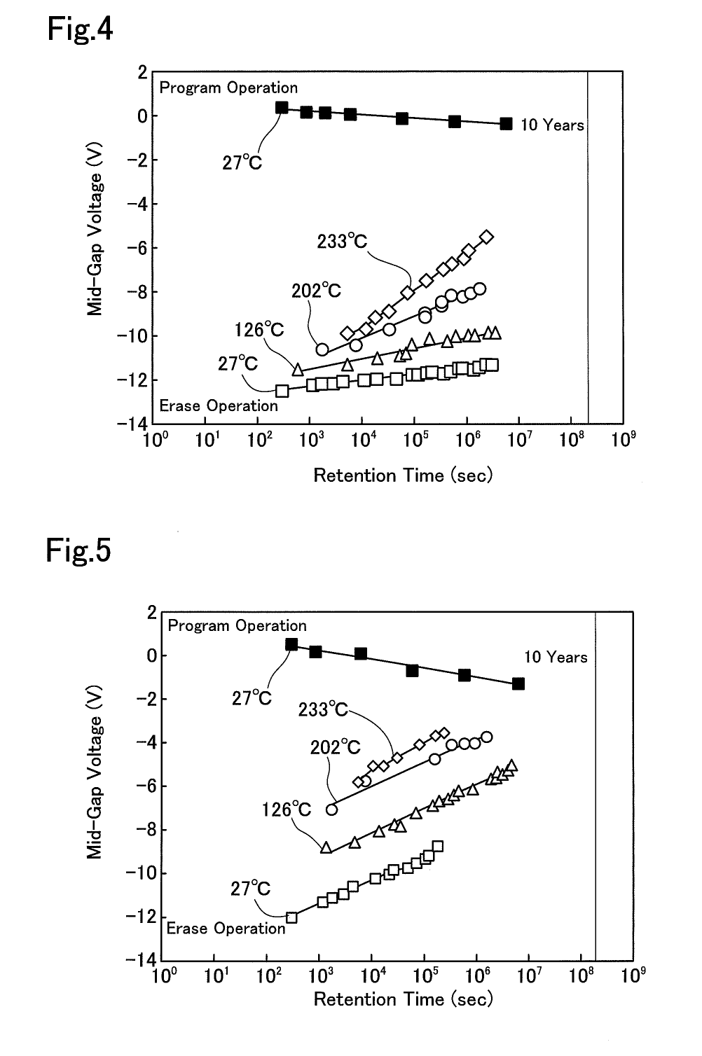

In this Example, a silicon nitride film having a thickness of 49.9 nm using SiH₄ gas and NH₃ gas as raw gases in amounts of 5 sccm and 200 sccm, respectively according to the catalytic chemical vapor deposition technique, under the following film-forming conditions: the film-forming temperature: 300° C.; the pressure in the vacuum chamber: 10 Pa; and the temperature of the catalyst: 1,700° C. The substrate provided thereon with the silicon nitride film thus prepared was subjected to program and erase operations while the program voltage was set at +22 V and the erase voltage was set at −25 V, then the mid-gap voltage of the silicon nitride film was determined at predetermined intervals of time, while the atmospheric temperature was set at 27° C., 126° C., 202° C. or 233° C. to thus evaluate the charge-retaining characteristics of the film. The results thus obtained are plotted on FIG. 4.

Moreover, as a comparative example, an Si₃N₄ film having a thickness of 48.5 nm was formed on a silicon substrate using silane dichloride (SiH₂Cl₂) gas and NH₃ gas as raw gases, according to the LPCVD technique at a film-forming temperature of 750° C., a pressure of 30 Pa and the resulting silicon nitride film was inspected for the charge-retaining characteristics using the same method described above. The results thus obtained are plotted on FIG. 5.

In FIGS. 4 and 5, the retention time (sec) is plotted as abscissa and the mid-gap voltage is plotted as ordinate. In this respect, the longer the time period during which the difference between the mid-gap voltages observed for the program and erase operations is maintained at a higher level, the more excellent the charge-retaining characteristics of the film.

If comparing the data plotted on FIG. 4 with those plotted on FIG. 5, it can be recognized that the silicon nitride film according to the present invention has higher charge-retaining characteristics as compared with those observed for the same film prepared according to the LPCVD technique. It can also be recognized that the silicon nitride film of the present invention has the charge retaining characteristics over not less than 10 years in the light of the results of the accelerated test carried out at 233° C.

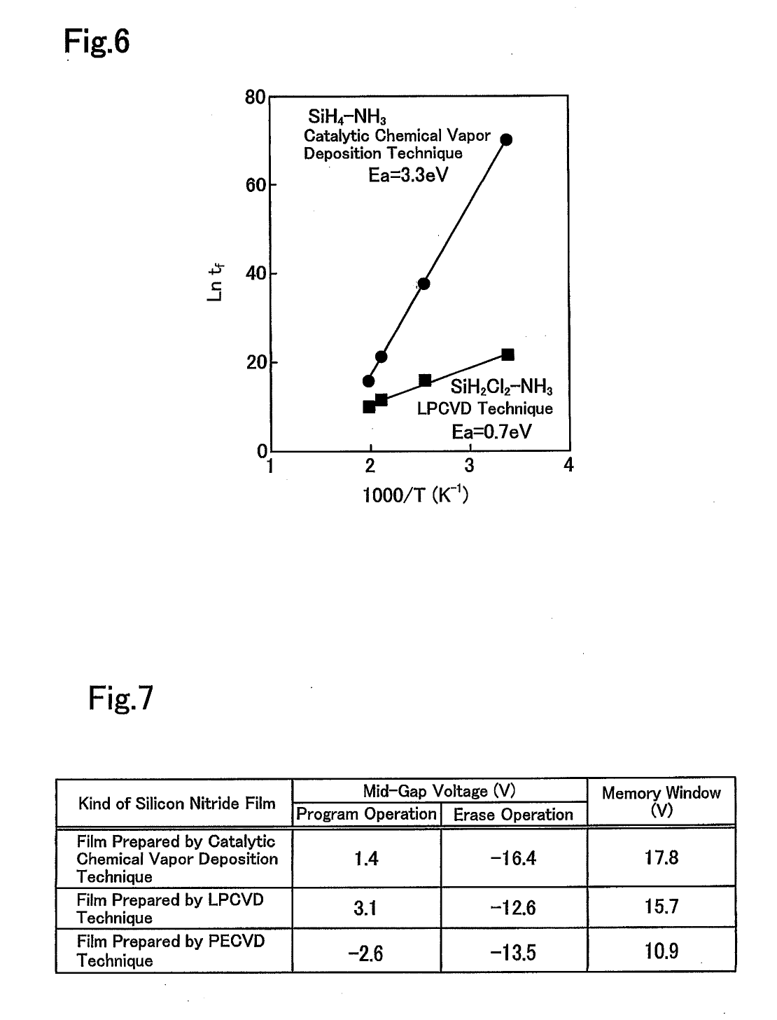

To evaluate the temperature dependency of the data plotted on FIGS. 4 and 5, Arrhenius plot is prepared while the temperature is plotted as abscissa and the activation energy (Lnt_{f}) is plotted as ordinate and the results thus obtained are shown in FIG. 6. As will be clear from the data plotted on FIG. 6, the silicon nitride film prepared according to catalytic chemical vapor deposition technique (SiH₄—NH₃ system, Cat-CVD technique: Ea=3.3 eV) has an activation energy 4 times higher than that observed for the silicon nitride film prepared according to the LPCVD technique (SiH₂Cl₂—NH₃ system, LPCVD technique: Ea=0.7 eV) and the trap levels (surface states) of these silicon nitride films are inherently different from one another. In other words, it would be presumed, in the case of the former, that a large quantity of energy is required to force out or expel a positive hole from the film after it is once trapped therein, that it is quite difficult to expel the positive hole trapped even if the temperature of the film is, for instance, raised to a higher level and that the silicon nitride film can thus retain charges over a long period of time.

As a comparative experiment, an Si₃N₄ film having a thickness of 56.2 nm was formed using SiH₄ gas, NH₃ gas and N₂ gas as raw gases, according to the plasma enhanced chemical vapor deposition (PECVD) technique at a film-forming temperature of 350° C. and the resulting silicon nitride film was inspected for the charge-retaining characteristics using the same method described above.

FIG. 7 shows the results obtained in the foregoing test for the evaluation of the charge-retaining characteristics of the Si₃N₄ film prepared in the foregoing comparative experiment, according to the PECVD technique, while comparing them with those observed for the silicon nitride film obtained in Example 2 according to the catalytic chemical vapor deposition technique and those observed for the Si₃N₄ film prepared according to the LPCVD technique.

The data plotted on FIG. 7 clearly indicate that the silicon nitride film prepared in Example 2 according to the catalytic chemical vapor deposition technique shows the highest memory window (memory window: 17.8 V) and that the memory window is reduced in the order of the silicon nitride film prepared according to the LPCVD technique (memory window: 15.7 V) and the silicon nitride film prepared according to the PECVD technique (memory window: 10.9 V).

### INDUSTRIAL APPLICABILITY

The present invention can thus provide a non-volatile semiconductor memory device which is provided with a charge storage film consisting of a silicon nitride film and having high charge-retaining characteristics and which is micronized and has a high degree of integration, and a method for the production of the same, as well as such a charge storage film. Accordingly, the present invention can be applied in the field of the semiconductor memory technique.

### EXPLANATION OF SYMBOLS

11 . . . Si substrate; 12 . . . tunnel insulating film; 13 . . . charge storage film; 14 . . . blocking insulating film; 15 . . . control gate electrode; 16 . . . source region; 17 . . . drain region; 21 . . . vacuum chamber; 22 . . . substrate-mounting table; 23 . . . nozzle; 24 . . . raw gas supply system; 25 . . . hole; 26 . . . substrate; 27 . . . catalyst; 28 . . . power supply; 29 . . . vacuum pump; 30 . . . variable valve; 31 . . . heating means.

1. A non-volatile semiconductor memory device characterized in that it comprises a tunnel insulating film on the top of a semiconductor substrate, a charge storage film on the top of the tunnel insulating film, a blocking insulating film on the top of the charge storage film, a control gate electrode arranged on the top of the blocking insulating film, and source/drain regions formed on the semiconductor substrate on the both sides of the control gate electrode, that the charge storage film is a silicon nitride film produced according to the catalytic chemical vapor deposition technique and that the ratio between the constituent elements: N/Si falls within the range of from 1.2 to 1.4.

2. The non-volatile semiconductor memory device as set forth in claim 1, wherein the content of the hydrogen atoms introduced into the silicon nitride film according to the catalytic chemical vapor deposition technique falls within the range of from 5 to 20 at %.

3. The non-volatile semiconductor memory device as set forth in claim 1, wherein the number, per unit volume, of the N—H bonds introduced into the silicon nitride film according to the catalytic chemical vapor deposition technique falls within the range of from 5×10²¹ to 5×10²² bonds/cm³.

4. A non-volatile semiconductor memory device characterized in that it comprises a tunnel insulating film on the top of a semiconductor substrate, a charge storage film on the top of the tunnel insulating film, a blocking insulating film on the top of the charge storage film, a control gate electrode arranged on the top of the blocking insulating film, and source/drain regions formed on the semiconductor substrate on the both sides of the control gate electrode, that the charge storage film is a silicon nitride film produced according to the catalytic chemical vapor deposition technique, that the ratio between the constituent elements: N/Si falls within the range of from 1.2 to 1.4, that the content of the hydrogen atoms introduced into the foregoing silicon nitride film according to the catalytic chemical vapor deposition technique falls within the range of from 5 to 20 at %, and that the number, per unit volume, of the N—H bonds introduced into the silicon nitride film according to the catalytic chemical vapor deposition technique falls within the range of from 5×10²¹ to 5×10²² bonds/cm³.

5. The non-volatile semiconductor memory device as set forth in claim 1, wherein the silicon nitride film is one prepared according to the catalytic chemical vapor deposition technique in which SiH₄ gas and NH₃ gas are introduced into a vacuum chamber and decomposed by bringing these gases into close contact with a heated catalyst and the resulting decomposition products are deposited on a heated surface of a subject arranged within the vacuum chamber to thus form a silicon nitride film.

6. The non-volatile semiconductor memory device as set forth in claim 5, wherein the silicon nitride film is one prepared according to the catalytic chemical vapor deposition technique, while the ratio of the introduced amount of the SiH₄ gas to that of the NH₃ gas: NH₃/SiH₄ is set at a level ranging from 1 to 500.

7. The non-volatile semiconductor memory device as set forth in claim 1, wherein the silicon nitride film is one prepared according to the catalytic chemical vapor deposition technique in which SiH₄ gas, NH₃ gas and H₂ gas are introduced into a vacuum chamber and decomposed by bringing these gases into close contact with a heated catalyst and the resulting decomposition products are deposited on a heated surface of a subject arranged within the vacuum chamber to thus form a silicon nitride film.

8. The non-volatile semiconductor memory device as set forth in claim 7, wherein the silicon nitride film is one prepared according to the catalytic chemical vapor deposition technique, while the ratios between the amounts of the introduced SiH₄ gas, NH₃ gas and H₂ gas or the ratio: (NH₃+H₂)/SiH₄ and the ratio: NH₃/(NH₃+H₂) are set at levels ranging from 1 to 500 and 0.01 to 1, respectively.

9. The non-volatile semiconductor memory device as set forth in claim 1, wherein the silicon nitride film is one prepared according to the catalytic chemical vapor deposition technique, in which the pressure in the vacuum chamber is set at a level of less than 100 Pa.

10. The non-volatile semiconductor memory device as set forth in claim 5, wherein the temperature of the heated surface of the subject ranges from 100 to 500° C.

11. The non-volatile semiconductor memory device as set forth in claim 1, wherein the catalyst consists of a member selected from the group consisting of at least one metal selected from W, Mo and Ta, and alloys each consisting of at least two of these metals.

12. The non-volatile semiconductor memory device as set forth in claim 1, wherein the temperature of the heated catalyst ranges from 1,500 to 2,000° C.

13. A method for the preparation of a non-volatile semiconductor memory device characterized in that it comprises the steps of forming a tunnel insulating film on a semiconductor substrate; forming, on the tunnel insulating film, a silicon nitride film serving as a charge storage film, in which the ratio between the constituent elements: N/Si falls within the range of from 1.2 to 1.4, according to the catalytic chemical vapor deposition technique; forming a blocking insulating film on the charge storage film; forming a control gate electrode on the blocking insulating film; and forming source/drain regions on the semiconductor substrate on the both sides of the control gate electrode.

14. The method for the preparation of a non-volatile semiconductor memory device as set forth in claim 13, wherein the content of the hydrogen atoms introduced into the foregoing silicon nitride film according to the catalytic chemical vapor deposition technique falls within the range of from 5 to 20 at %.

15. The method for the preparation of a non-volatile semiconductor memory device as set forth in claim 13, wherein the number, per unit volume, of the N—H bonds introduced into the silicon nitride film according to the catalytic chemical vapor deposition technique falls within the range of from 5×10²¹ to 5×10²² bonds/cm³.

16. The method for the preparation of a non-volatile semiconductor memory device as set forth in claim 13, wherein the silicon nitride film is prepared according to the catalytic chemical vapor deposition technique in which SiH₄ gas and NH₃ gas are introduced into a vacuum chamber and decomposed by bringing these gases into close contact with a heated catalyst, and the resulting decomposition products are deposited on a heated surface of a subject arranged within the vacuum chamber to thus form a silicon nitride film.

17. The method for the preparation of a non-volatile semiconductor memory device as set forth in claim 16, wherein the silicon nitride film is prepared according to the catalytic chemical vapor deposition technique, while the ratio of the introduced amount of the SiH₄ gas to that of the NH₃ gas: NH₃/SiH₄ is set at a level ranging from 1 to 500.

18. The method for the preparation of a non-volatile semiconductor memory device as set forth in claim 13, wherein the silicon nitride film is prepared according to the catalytic chemical vapor deposition technique in which SiH₄ gas, NH₃ gas and H₂ gas are introduced into a vacuum chamber and decomposed by bringing these gases into dose contact with a heated catalyst and the resulting decomposition products are deposited on a heated surface of a subject arranged within the vacuum chamber to thus form a silicon nitride film.

19. The method for the preparation of a non-volatile semiconductor memory device as set forth in claim 18, wherein the silicon nitride film is prepared according to the catalytic chemical vapor deposition technique, while the ratios between the amounts of the introduced SiH₄ gas, NH₃ gas and H₂ gas or the ratio: (NH₃+H₂)/SiH₄ and the ratio: NH₃/(NH₃+H₂) are set at levels ranging from 1 to 500 and 0.01 to 1, respectively.

20. The method for the preparation of a non-volatile semiconductor memory device as set forth in claim 13, wherein the silicon nitride film is prepared according to the catalytic chemical vapor deposition technique, in which the pressure in the vacuum chamber is set at a level of less than 100 Pa.

21. The method for the preparation of a non-volatile semiconductor memory device as set forth in claim 16, wherein the temperature of the heated surface of the subject ranges from 100 to 500° C.

22. The method for the preparation of a non-volatile semiconductor memory device as set forth in claim 16, wherein the catalyst consists of a material selected from the group consisting of at least one metal selected from W, Mo and Ta, and alloys each consisting of at least two of these metals.

23. The method for the preparation of a non-volatile semiconductor memory device as set forth in claim 16, wherein the temperature of the heated catalyst ranges from 1,500 to 2,000° C.

24. A charge storage film characterized in that it is a silicon nitride film, which is prepared according to the catalytic chemical vapor deposition technique and whose ratio between the constituent elements: N/Si falls within the range of from 1.2 to 1.4.

25. The charge storage film as set forth in claim 24, wherein the silicon nitride film contains hydrogen atoms which are introduced into the silicon nitride film according to the catalytic chemical vapor deposition technique, in a content falling within the range of from 5 to 20 at %.

26. The charge storage film as set forth in claim 24 of 45, wherein the silicon nitride film has the number, per unit volume, of the N—H bonds introduced into the silicon nitride film according to the catalytic chemical vapor deposition technique, which falls within the range of from 5×10²¹ to 5×10²² bonds/cm³.

27. The non-volatile semiconductor memory device as set forth in claim 4, wherein the silicon nitride film is one prepared according to the catalytic chemical vapor deposition technique in which SiH₄ gas and NH₃ gas are introduced into a vacuum chamber and decomposed by bringing these gases into close contact with a heated catalyst and the resulting decomposition products are deposited on a heated surface of a subject arranged within the vacuum chamber to thus form a silicon nitride film.

28. The non-volatile semiconductor memory device as set forth in claim 4, wherein the silicon nitride film is one prepared according to the catalytic chemical vapor deposition technique in which SiH₄ gas, NH₃ gas and H₂ gas are introduced into a vacuum chamber and decomposed by bringing these gases into close contact with a heated catalyst and the resulting decomposition products are deposited on a heated surface of a subject arranged within the vacuum chamber to thus form a silicon nitride film.

29. The non-volatile semiconductor memory device as set forth in claim 4, wherein the silicon nitride film is one prepared according to the catalytic chemical vapor deposition technique, in which the pressure in the vacuum chamber is set at a level of less than 100 Pa.

30. The non-volatile semiconductor memory device as set forth in claim 4, wherein the temperature of the heated catalyst ranges from 1,500 to 2,00000.
